(19) United States
(12) Patent Application Publication
(10) Pub. No.: US 2018/0036797 A1
(43) Pub. Date: Feb. 8, 2018

(54) FURNACE FOR THE PRODUCTION OF COMPONENTS MADE OF SUPERALLOY BY MEANS OF THE PROCESS OF INVESTMENT CASTING

(71) Applicant: EUROPEA MICROFUSIONI AEROSPAZIALI S.P.A., Morra de Sanctis (IT)

(72) Inventors: Pasquale CORRERA, Morra de Sanctis (IT); Giovanni PENNELLA, Morra de Sanctis (IT); Pasquale SANTORO, Morra de Sanctis (IT); Gerardo MARIANI, Morra de Sanctis (IT)

(21) Appl. No.: 15/556,569

(22) PCT Filed: May 2, 2016
(86) PCT No.: PCT/IT2016/000112

§ 371 Date: Sep. 7, 2017

(30) Foreign Application Priority Data
Apr. 30, 2015 (IT) 102015000013617

(51) Int. Cl. B22D 27/04

(52) U.S. Cl. CPC B22D 27/045; C30B 11/00

(57) ABSTRACT

The present invention concerns a furnace for the production of components made of superalloy by means of the process of investment casting.

The present invention relates to a support assembly for supporting the cooling plate of a melting furnace, in particular of the resistive type, for the production of superalloy components by using the investment casting process.

More precisely, the present invention refers to melting furnaces, in particular of the resistive type, operating under high vacuum, aimed to the production, by means of the lost wax casting process of or investment casting, of superalloy components with grain structure of the directional type (DS)/single crystal (SX), for aerospace, marine and industrial turbines.

The lost wax casting furnaces, in particular of the resistive type, generally provide a melting chamber, a thermal chamber comprised of a hollow graphite cylinder, or internally, by induction, to the passage of an electric current, or graphite hot chamber, which, externally heated by a graphite resistance, acts as an active element for the radiation heating of a ceramic shell, used as a mold for the metal casting, internally loaded and positioned on the chill plate or cooling plate, usually made of copper, cooled by a water flow, and moved by a piston for moving the ceramic shell from the thermal chamber to the extraction chamber or cold chamber, arranged below said heating chamber, and vice versa.

An example of a known furnace is described in the European patent application EP 0 559 251 A1.

In the following reference will be made to ceramic material shells, i.e. internally shaped refractory material bodies, having cavities representing at the geometrical-dimensional level the negative shape of the final production of components, i.e. superalloy components for aerospace, naval and industrial turbines.

The production process of components with the grain structure of the DS/SX type is mainly based on setting a high modulus (of the order of 10÷100° C./cm, with specific values for each component category) and well determined direction (unidirectional, along the gravitational axis, coincident with the main axis of the component) spatial thermal gradient during the step of solidification of the superalloy, by means of:

the generation and maintenance of a given thermal field inside the graphite hot chamber and a of certain cooling of the chill plate (cooling water temperature in the range of 20÷24° C.); and

the use of a specific extraction profile of the ceramic shell from the thermal chamber to the extraction chamber according to a controlled descent program of the piston (speed extraction in the range of 0.1÷10 mm/min).

Just to maintain said thermal field optimum conditions inside the thermal chamber, the thermal chamber is sized to house ceramic shells having dimensions included in a very limited range.

Therefore, to be able to house ceramic shells having a greater height, in order to obtain superalloy components larger in the axial direction, at present it would be necessary purchasing additional furnaces having the thermal chamber of larger dimensions.

The above represents a limit, both in terms of cost and space.

The object of the present invention is therefore that of overcoming the drawbacks of the prior art, by modifying the known casting furnaces, so that they are able to house ceramic shells of different sizes, without the need of buying a new furnace or rebuild the thermal chamber.

It is therefore the object of the present invention a furnace for the production of components made of superalloy by means of the process of investment casting, said furnace comprising a fusion chamber, a warm chamber or thermal chamber and a cold chamber or extraction chamber arranged under said thermal chamber, a thermal interface zone, arranged between said warm chamber and said cold chamber, a cooling plate for the housing of a ceramic shell, said cooling plate having a bottom portion, and a support assembly for said cooling plate, said support assembly comprising: a piston having a top end, and a height, a first spacer flange, having a first height, having a top portion and a bottom portion, said first flange being configured in order to be able to be removably coupled to said top end of said piston and to said bottom portion of said cooling plate, a second spacer flange, having a second height, having a top portion and a bottom portion, said second flange being configured in order to be removably coupled to said bottom portion of said cooling plate and, alternatively, to said top end of said piston or to said top portion of said first flange, the size of said thermal chamber being so configured to house a ceramic shell on said cooling plate in order to maintain an optimum thermal field within said thermal chamber, the height of said piston and the height of said second flange being determined so that when said support assembly supports said cooling plate, said support assembly is able to alternatively assume both a first arrangement, wherein the top portion of said second flange is coupled to said cooling plate and the bottom portion is coupled to said piston or to said first flange in turn coupled to said piston, maintaining said cooling plate in correspondence of said thermal interface zone of said furnace raising said plate of a distance, so as to house on said cooling plate a first ceramic shell, with an optimum thermal field within the thermal chamber, and a second arrangement, wherein said first flange is coupled at the bottom to said piston and at the top to said cooling plate maintaining said cooling plate in correspondence of said interface zone for the housing on said cooling plate of a second ceramic shell having a higher height than said first ceramic shell of said distance at an optimum thermal field within the thermal chamber.

Still according to the invention, the height of said second flange can be equal to the height of the first flange in addition to said distance, so that in said first arrangement, the top portion of said second flange is coupled to said cooling plate and the bottom portion is coupled to said piston maintaining said cooling plate in correspondence of said interface zone of said furnace raising said plate of said distance, so as to house on said cooling plate a first ceramic shell.

Always according to the invention, the height of said second flange can be equal to said distance, so that in said first arrangement, the top portion of said second flange is coupled to said cooling plate and the bottom portion is coupled to said first flange, that in turn is coupled to said piston, maintaining said cooling plate in correspondence of said interface zone of said furnace raising said plate of said distance, so as to house on said cooling plate a first ceramic shell.

Particularly, according to the invention, said flanges and said piston can comprise at least a supply channel for supplying a cooling fluid to said cooling plate, and at least a return channel for the return of said cooling fluid from said cooling plate.

More particularly, according to the invention, said flanges can comprise a plurality of first holes for the insertion of fixing elements to said cooling plate.

Furthermore, according to the invention, said flanges can comprise a plurality of second holes for the insertion of fixing elements to said piston.

Further, according to the invention, said flanges can comprise a first housing in correspondence of the top portion in order to house a first seal element between said flanges and said cooling plate, said first seal element being preferably an O-ring.

Still according to the invention, said flanges can comprise a second housing in correspondence of the bottom portion for housing a second seal element between said flanges and said top end of said piston, said second seal element being preferably an O-ring.

Furthermore, according to the invention, said distance can be comprised between 1 cm and 3 cm, preferably equivalent to 2.54 cm.

Always according to the invention, said furnace can provide a baffle plate for the cooling liquid between said flange and said cooling plate.

Finally, it is object of the present invention a method for modifying a furnace as described in the above, wherein the height of an existing piston is reduced of said distance, so as to obtain said piston height.

The invention will be now described, for illustrative but not limitative purposes, with particular reference to the figures of the enclosed drawings, wherein:

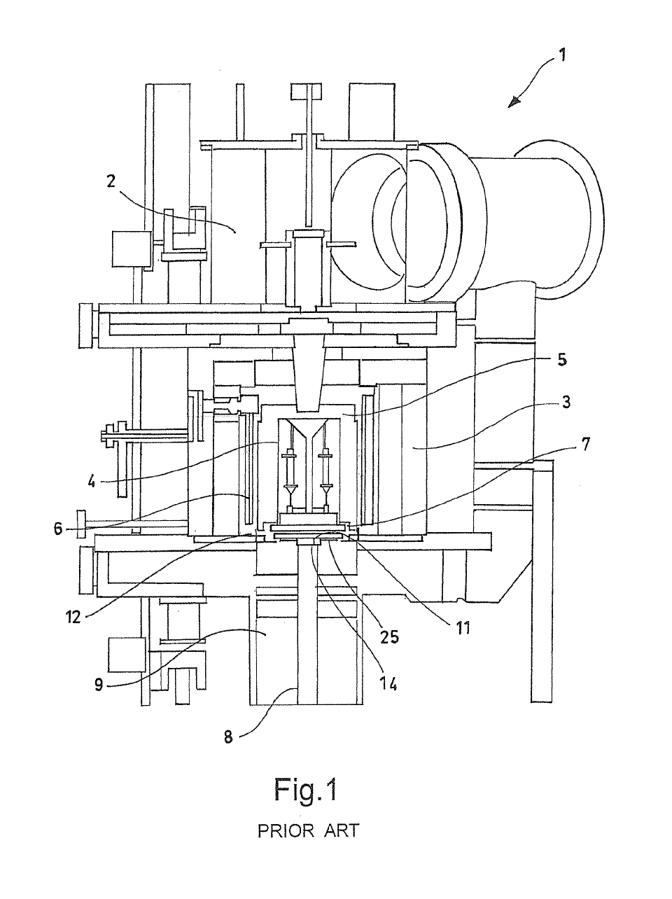

FIG. 1 shows a front view of a casting furnace having a support assembly of the cooling plate according to the prior art;

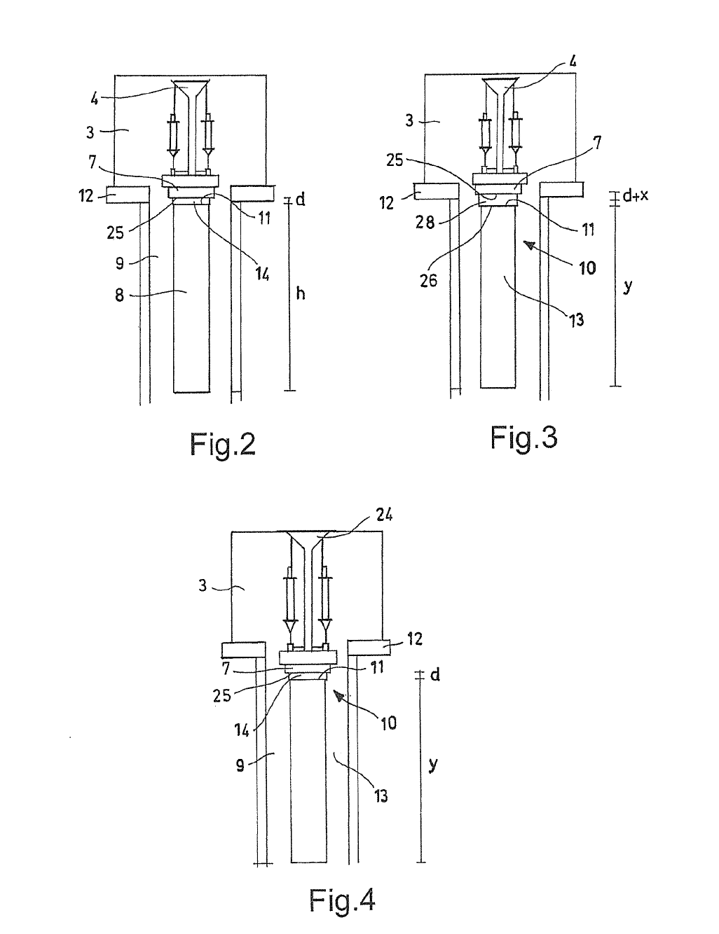

FIG. 2 shows a front view of the support assembly of the prior art of FIG. 1;

FIG. 3 shows a front view of a support assembly of the cooling plate of a resistive furnace according to the invention according to a first embodiment and in a first arrangement or low arrangement;

FIG. 4 shows a front view of the support assembly of FIG. 3 in a second arrangement or high arrangement;

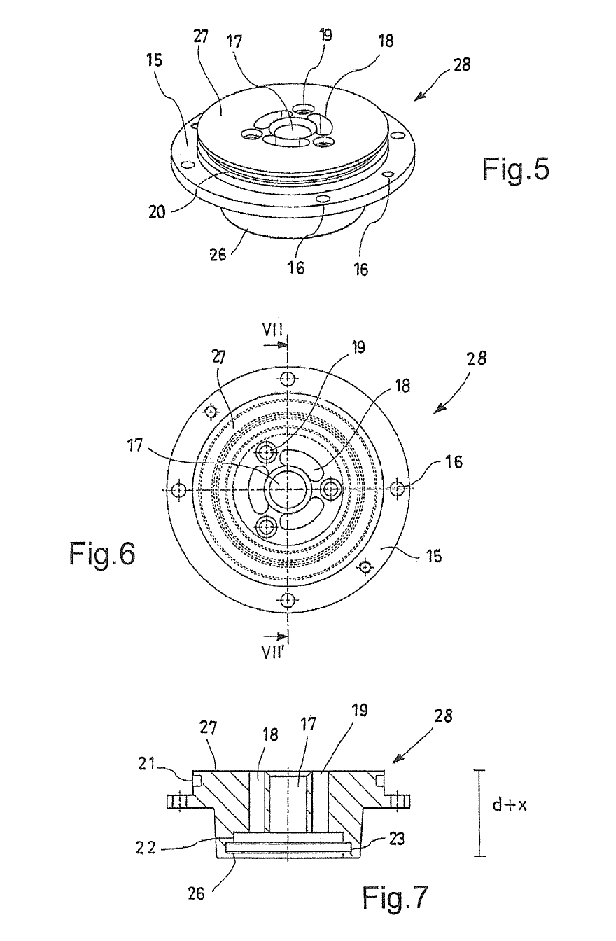

FIG. 5 shows a perspective view of the support assembly of the flange in the arrangement of FIG. 3;

FIG. 6 shows a top view of the flange of FIG. 5;

FIG. 7 shows a sectional view of the flange of FIG. 5 along the plane VII-VII′ of FIG. 6;

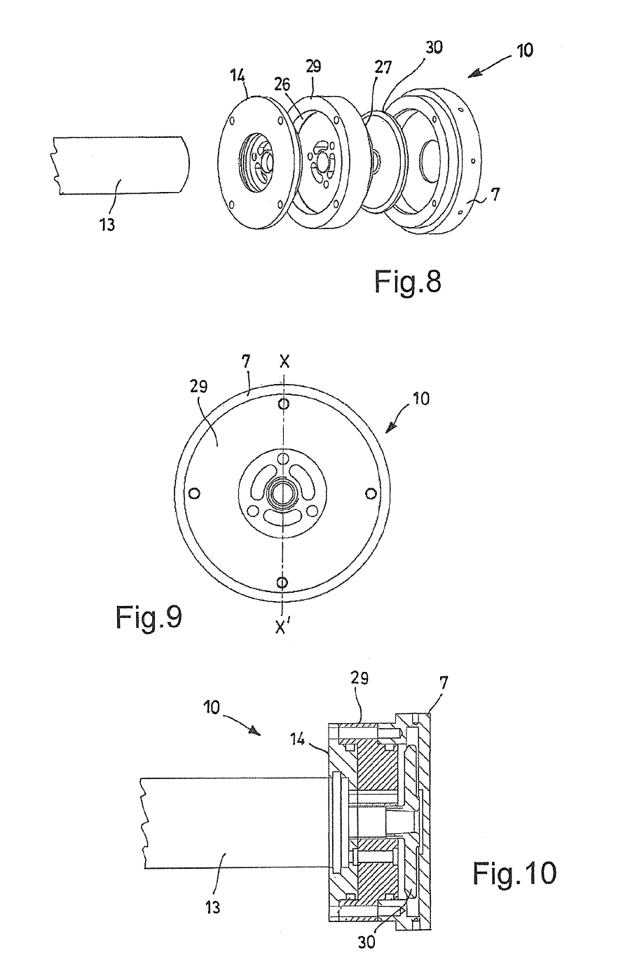

FIG. 8 shows an exploded view of a support assembly according to the invention according to a second embodiment;

FIG. 9 shows a top view of the support assembly of FIG. 8;

FIG. 10 shows a section view of the support assembly of FIG. 8 taken along the plane X-X′ of FIG. 9;

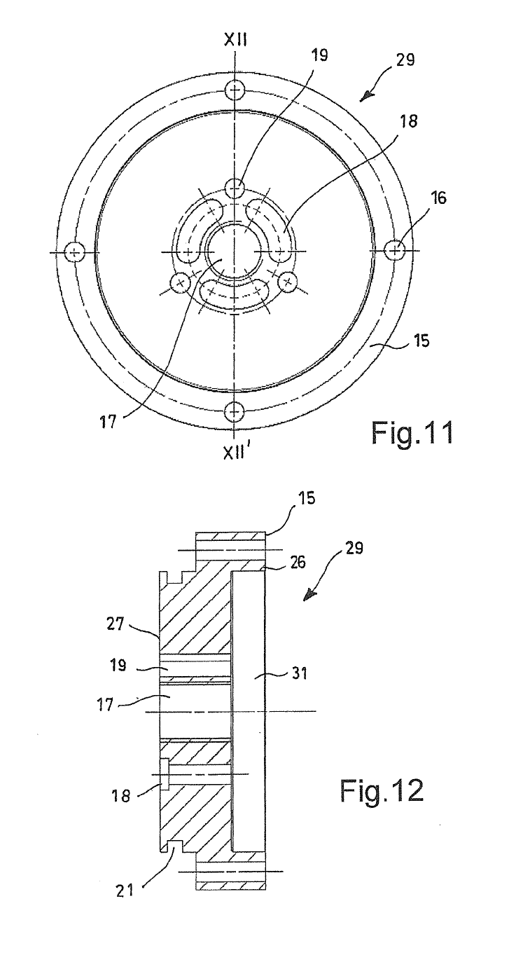

FIG. 11 shows a top view of the further flange of the support assembly of FIG. 8; and

FIG. 12 shows a section view of the flange of FIG. 11 taken along the plane XII-XII′.

Referring to FIGS. 1 and 2, it is observed a resistive furnace 1 according to the known technique.

A resistive furnace or investment casting furnace 1 generally comprises a melting chamber 2, where the fusion of the superalloy occurs, a thermal chamber or hot chamber 3, arranged below the melting chamber 2, wherein it is housed a and heated a first ceramic shell 4 having standard dimensions, in which the molten alloy from the melting chamber 2 is poured.

Moreover, furnace 1 comprises an extraction chamber or cold chamber 9 arranged below the heating chamber 3, for the extraction of the first ceramic shell 4 from the furnace 1, where the solidification and cooling of the superalloy take place with the generation of the desired grain structure.

Particularly, the thermal chamber or hot chamber 3 comprises a hollow graphite cylinder 5, also called hot graphite chamber, a graphite resistance 6 able to heat the hollow cylinder 5 and the first ceramic shell 4 positioned within the same, a cooling plate 7, preferably made up of copper, which is cooled by the passage of a cold fluid stream, in particular water, on which it is arranged the first ceramic shell 4, a piston 8, having a height h, with the upper end 11 coupled to the lower portion 26 of a spacer flange 14, having a height d, with an upper portion 27 able to be coupled to the lower portion 25 of the cooling plate 7 and acting on the same to electrically or mechanically move the cooling plate 7 on which it is arranged the first ceramic shell 4 which is extracted from the heating chamber 3 (as shown in FIG. 1) and moved to the extraction chamber 9.

Preferably the thermal chamber 3 has a height of the useful charge volume of the ceramic shell 4 of about 12.5 inches.

Between the heating chamber 3 and the extraction chamber 9 a thermal interface area 12 is arranged, in particular a thermal deflector 12 or ceramic baffle with thermal shielding role between the two hot 3 and cold 9 chambers, fundamental to ensure the thermal gradient necessary for the development of the desired grain structure in the superalloy component.

As it can be observed in FIG. 1 representing the resistive furnace 1 according to the prior art and considering the limitations related to the physical dimensions during the loading phase of the ceramic shell, the resistive furnace 1 is not capable of housing a second ceramic shell having a height greater than the standard size first ceramic shell 4.

Moreover, said thermal chamber 3 would not be in any case able of housing a third ceramic shell of smaller dimensions than the first ceramic shell 4, because the furnace 1 would no longer be able to guarantee an optimal temperature range for the third ceramic shell, compromising the yield of the physical-chemical process that is at the origin of the directional growth process of single grains (DS structure) or that determines the direction of the single crystal (SX structure) in the molten metal for the formation of superalloy components.

In FIGS. 3 and 4 it is shown the support assembly according to the invention according to a first embodiment, for supporting the cooling plate 7 of a resistive furnace 1 and indicated by the reference number 10.

The support assembly 10 according to the invention provides a piston 13, configured to replace the piston 8 according to the prior art, and having a height y so that, in a first arrangement of the support assembly 10 shown in FIG. 3, when the upper end 11 of the piston 13 is coupled to the second flange 28, the cooling plate 7 comes to be at a height not lower than, and not higher than, the thermal interface zone 12 of the furnace 1, in other words is to be located, in correspondence of the upper stroke end, within the area of thermal action of the heat deflector 12 as specified below.

Furthermore, the support assembly 10 according to the invention comprises a second spacer flange 28, having a d+x height, with a bottom portion 26 capable of mating with the upper end 11 of the piston 13, and an upper portion 27 capable of mating with the lower portion 25 of the cooling plate 7.

The d+x height of the second spacer flange 28 and the height y of the piston 13 are configured so that, when the support assembly 10 according to the invention supports the cooling plate 7 of the resistive furnace, the support assembly 10 alternately assumes a first arrangement (shown in FIG. 3), wherein the second spacer flange 28 is coupled to the piston 13 and the cooling plate 7, in order to accommodate a first ceramic shell 4; and

a second arrangement (shown in FIG. 4) in which the upper end 11 of the piston 13 is coupled to the lower portion 25 of the cooling plate 7 by means of the first spacer flange 14, in order to accommodate a second ceramic shell 24, having a height greater than the first ceramic shell 4 of a distance x substantially equivalent to the height difference between the first flange 14 and second flange 28.

Preferably, the height of the first ceramic shell 4 is about 11.5 inches and the height of the second ceramic shell 24 is about 12.5 inches.

Said support assembly 10 according to the invention can be employed on resistive furnaces 1 configured to accommodate the first ceramic shells 4, as shown in the enclosed figures, wherein the prior art piston 8 is shortened in height by a distance equivalent to x or y height, in other words, replaced with a new piston 13 having a height y equal to h−x height, in order to allow the housing of second ceramic shells 24, i.e. higher than the first ceramic shells 4 by a distance x. And in which the second flange 28 has a height equal to d+x, so as to restore the original state, to allow housing the first ceramic shells 4, maintaining an optimal thermal field.

Preferably, x is between 1 cm and 3 cm, preferably equal to 2.54 cm.

Moreover, the support assembly according to the invention can also be advantageously used in furnaces configured to house only seconds ceramic shells. In fact, using the flange according to the invention between the piston of this type of furnace and the cooling plate, it raises the height of the cooling plate and it is possible to house the first ceramic shells, having a height smaller than the second ceramic molds, maintaining an optimal temperature field.

The advantages of the support assembly according to the invention are given by the reduced costs both in economic terms for shortening the piston and for the development of the spacer flange without the need of modifying the other elements or software of the furnace, both as regards the time required for the introduction/removal of the spacer flange and the switch between the two casting arrangements with the first ceramic shell of standard size and with the second ceramic shell of higher height.

The simplicity of the method of conversion between the two assembly support arrangements insures the possibility of having a single furnace on which either ceramic shells of standard sizes, and higher height ceramic shells or tall ceramic shells can be casted, with necessary machine downtime for the insertion/removal of the spacer flange very small.

As shown in FIGS. 5-7, the second spacer flange 28, preferably made out of the same steel of the piston, most preferably stainless steel, in particular of type AISI 316, has at least one cooling fluid flow channel 17 for the flow of the cooling fluid of the cooling plate 7 (same geometry of the corresponding channel present within the piston 13), and one or more cooling fluid return channels 18 for returning the cooling fluid from the cooling plate 7, particularly preferably three, and having the same geometry of the corresponding channels present within the piston 13.

In addition, the second spacer flange 28 may have a housing base 15 to support the cooling plate 7, a plurality of first holes 16, formed on said housing base 15, for fastening elements, in particular, positioning and fixing screws, of the cooling plate 7.

Still, the second spacer flange 28 may have a seat 22 for the upper end 11 of the piston 13, and a plurality of second holes 19 for fastening elements, in particular the positioning and fixing screws, to the piston 13.

To improve the sealing of the flange 28 when coupled to the cooling plate 7 and the piston 13, the flange 28 may have a first housing 21 for housing an O-ring 20 for sealing the cooling fluid of the cooling plate 7 in the connecting area with said plate 7, and a second housing 23 for housing a second O-ring 20 for sealing the cooling water of the cooling plate 7 in the junction zone with the piston 13.

The features of the second flange 28 described can also be applied to the first flange 14.

In FIGS. 8-12 there is shown a second embodiment of the support assembly 10 according to the invention.

Said support assembly 10 comprises the piston 13, the first flange 14 and a third flange 29.

Said third flange 29 has a height equivalent to x, so that when said support assembly 10 is in said first arrangement, said third flange 29 is coupled to the first flange 14 and to the cooling plate 7 while maintaining said cooling plate 7 at said interface zone 12 of said furnace 1, so as to house the first ceramic shell 4 onto said cooling plate 7.

Said solution advantageously allows to keep the first flange 14 always coupled to the piston 13 and to insert or remove the third flange 29 between the first flange 14 and the cooling plate 7 according to the casting required, respectively for the first ceramic shell 4 or for the second ceramic shell 24.

Particularly, the third flange 29 has at least one cooling fluid flow channel 17 for the flow of the cooling fluid of the cooling plate 7 (the same geometry of the corresponding channel present within the piston 13 and the first flange 14), and one or more return channels 18 of the cooling fluid from the cooling plate 7, particularly preferably three, and having the same geometry of the corresponding channels present inside the piston 13 and the first flange 14.

Furthermore, the third spacer flange 29 may have a housing base 15 to support the cooling plate 7, a plurality of first holes 16, formed on said housing base 15, for fastening elements, in particular, positioning and fixing screws, to the first flange 14 and to the cooling plate 7 and a plurality of second holes 19 for fastening elements, in particular positioning and fixing screws, to the piston 13.

Still, the third spacer flange 29 may have a seat 31 for housing the first flange 14.

To improve the sealing of the flange 29 in the coupling to the cooling plate 7, the third flange 29 may have a first housing 21 for housing an O-ring 20 for sealing the cooling fluid of the cooling plate 7 in the junction zone with said plate 7.

Preferably, a deflector 30 of the cooling liquid can be interposed between the first flange 14, or between the second flange 28, and the cooling plate 7, as shown in FIGS. 8-10.

In the above, preferred embodiments have been described and the variants of the present invention have been suggested, but it is to be understood that the skilled in the art can introduce modifications and changes, without departing from the scope of the invention, as defined by the enclosed claims.

1. Furnace for the production of components made of superalloy by means of the process of investment casting,
said furnace comprising a fusion chamber, a warm chamber or thermal chamber and a cold chamber or extraction chamber arranged under said thermal chamber, a thermal interface zone, arranged between said warm chamber and said cold chamber, a cooling plate for the housing of a ceramic shell, said cooling plate having a bottom portion, and a support assembly for said cooling plate,
said support assembly comprising
a piston having a top end and a height,
a first spacer flange, having a first height, having a top portion and a bottom portion, said first flange being configured in order to be able to be removably coupled to said top end of said piston and to said bottom portion of said cooling plate,
a second spacer flange, having a second height, having a top portion and a bottom portion said second flange being configured in order to be removably coupled to said bottom portion of said cooling plate and, alternatively, to said top end of said piston or to said top portion of said first flange,
the size of said thermal chamber being so configured to house a ceramic shell on said cooling plate in order to maintain an optimum thermal field within said thermal chamber,
the height of said piston and the height of said second flange being determined so that when said support assembly supports said cooling plate, said support assembly is able to alternatively assume both
a first arrangement, wherein the top portion of said second flange is coupled to said cooling plate and the bottom portion is coupled to said piston or to said first flange in turn coupled to said piston, maintaining said cooling plate in correspondence of said thermal interface zone of said furnace raising said plate of a distance, so as to house on said cooling plate a first ceramic shell, with an optimum thermal field within the thermal chamber, and
a second arrangement, wherein said first flange is coupled at the bottom to said piston and at the top to said cooling plate maintaining said cooling plate in correspondence of said interface zone for the housing on said cooling plate of a second ceramic shell having a higher height than said first ceramic shell of said distance at an optimum thermal field within the thermal chamber.

2. Furnace according to claim 1, characterized in that the height of said second flange is equal to the height of the first flange in addition to said distance, so that in said first arrangement, the top portion of said second flange is coupled to said cooling plate and the bottom portion is coupled to said piston maintaining said cooling plate in correspondence of said interface zone of said furnace raising said plate of said distance, so as to house on said cooling plate a first ceramic shell.

3. Furnace according to claim 1, characterized in that the height of said second flange is equal to said distance, so that in said first arrangement, the top portion of said second flange is coupled to said cooling plate and the bottom portion is coupled to said first flange, that in turn is coupled to said piston, maintaining said cooling plate in correspondence of said interface zone of said furnace raising said plate of said distance, so as to house on said cooling plate a first ceramic shell.

4. Furnace according to claim 1, characterized in that said flanges and said piston comprise at least a supply channel for supplying a cooling fluid to said cooling plate, and at least a return channel for the return of said cooling fluid from said cooling plate.

5. Furnace according to claim 1, characterized in that said flanges comprise a plurality of first holes for the insertion of fixing elements to said cooling plate.

6. Furnace according to claim 1, characterized in that said flanges comprise a plurality of second holes for the insertion of fixing elements to said piston.

7. Furnace according to claim 1, characterized in that said flanges comprise a first housing in correspondence of the top portion in order to house a first seal element between said flanges and said cooling plate, said first seal element being preferably an O-ring.

8. Furnace according to claim 1, characterized in that said flanges comprise a second housing in correspondence of the bottom portion for housing a second seal element between said flanges and said top end of said piston, said second seal element being preferably an O-ring.

9. Furnace according to claim 1, characterized in that said distance is comprised between 1 cm and 3 cm, preferably equivalent to 2.54 cm.

10. Furnace according to claim 1, characterized in providing a baffle plate for the cooling liquid between said flange and said cooling plate.

11. Method for modifying a furnace according to claim 1, wherein the height of an existing piston is reduced of said distance, so as to obtain said piston height.
